(19) United States
(12) Patent Application Publication
(10) Pub. No.: US 2005/0260838 A1
(43) Pub. Date: Nov. 24, 2005

(54) Methods and systems for dopant profiling

(75) Inventors: Daniel F. Downey, Gloucester, MA (US); Edwin A. Arevalo, Haverhill, MA (US)

Correspondence Address: Mark Superko;Varian Semiconductor Equipment Associates, Inc., 35 Dory Lane, Gloucester, MA, 01930-2297, US

(73) Assignee: Varian Semiconductor Equipment Associates, Inc., Gloucester, MA (US)

(21) Appl. No.: 10/434,973

(22) Filed: May 9, 2003

Related U.S. Application Data
(60) Provisional application No. 60/379,692, filed on May 10, 2002.

(51) Int. Cl. H01L 21/425

(52) U.S. Cl. 438/527; 438/529; 438/530

(57) ABSTRACT

A method for activating a first ionic species implanted in a semiconductor, including annealing the semiconductor using a controlled diffusion annealing, and controlling the oxygen content during the annealing to redistribute the first ionic species such that the abruptness of the implanted profile is increased after the annealing. Also, a method is provided for forming a junction in a semiconductor, including implanting a first ionic species in the semiconductor, post-implanting at least one second ionic species where the at least one second ionic species includes at least one of an atomic weight and a molecular weight that is substantially the same or greater than at least one of the first ionic species' atomic weight and molecular weight, and, annealing the semiconductor using a controlled diffusion annealing, where the abruptness of the profile is decreased after annealing such that the junction dimensions are minimized with respect to the junction dimensions of the as-implanted profile of the first ionic species.

This application claims priority to U.S. Ser. No. 60/379,692, entitled “Methods and Systems for Dopant Profiling,” filed on May 10, 2002, naming Daniel F. Downey and Edwin A. Arevalo as inventors, the contents of which are herein incorporated by reference in their entirety.

### INCORPORATION BY REFERENCE

This provisional application incorporates herein by reference in its entirety, U.S. Ser. No. 10/115,211, filed Apr. 1, 2002, and naming DANIEL F. DOWNEY and EDWIN A. AREVALO as inventors, entitled “DOPANT DIFFUSION AND ACTIVATION CONTROL WITH ATHERMAL ANNEALING”.

### BACKGROUND

(1) Field

The disclosed methods and systems relate generally to dopant diffusion and activation control, and more particularly to dopant profiling.

(2) Description of Relevant Art

Conventional ion implantation systems include ionizing a dopant material such as boron, accelerating the ions to form an ion beam having a given energy level, and directing the ion beam energy at a semiconductor surface or wafer to introduce the dopant material to the semiconductor and alter the conductivity properties of the semiconductor. Once the ions are embedded into the crystalline lattice of the semiconductor, the ions can be activated using a process known as rapid thermal annealing (RTA) or rapid thermal process (RTP). During RTA, the semiconductor can be introduced to a furnace to heat the semiconductor at a prescribed temperature and for a prescribed time. RTA can also cure defects in the crystalline structure that can be caused by the ion implantation.

The processes of ion implantation and RTP contribute to the depth of the implanted region, known as the junction depth. The junction depth from ion implantation is based on the energy of the ions implanted into the semiconductor and the atomic or molecular weight of implanted ions.

Shallow implanted regions can be formed using low-energy ion beams, and preferably, with an ion implant having a heavier atomic or molecular weight rather than a lighter weight. Unfortunately, traditional methods of RTA include raising the temperature of the silicon to ranges nearing 1100-1200 degrees Celsius, which can approach the melting temperature of the silicon. Accordingly, RTA can further increase the implanted junction depth as high temperatures of the RTA process cause further diffusion of the implanted region.

The increase in junction depth can be particularly troublesome when considered with respect to a continuing and expanding demand for smaller devices, and hence shallower junction depths. The International Technology Roadmap for Semiconductors (ITRS) provides a roadmap for ultra shallow junctions that includes low sheet resistances where such low sheet resistance translates to high dopant activation.

### SUMMARY

The disclosed methods and systems include a method for activating a first ionic species implanted in a semiconductor, where the method includes annealing the semiconductor using a controlled diffusion annealing, and, controlling the oxygen content during the annealing to redistribute the first ionic species, where the profile of the first ionic species is controlled such that the abruptness of the profile is increased after annealing such that the junction dimensions of width and depth are minimized with respect to the as-implanted dimensions. The controlled diffusion annealing includes annealing for less than five seconds, and can include at least one of Solid Phase Epitaxy (SPE), Flash Rapid Thermal Annealing (Flash RTP), sub-melt laser annealing, microwave annealing, and Radio Frequency (RF) annealing. The oxygen content can be controlled based on an oxygen content that is further based on at least one of the controlled diffusion annealing, a temperature at which the controlled diffusion annealing is performed, a time for which the controlled diffusion annealing is performed, the first ionic species, and an ionic species other than the first ionic species that may also be implanted.

The methods and systems also include a method for forming a junction in a semiconductor, where the method includes implanting a first ionic species in the semiconductor, post-implanting at least one second ionic species where the at least one second ionic species includes at least one of an atomic weight and a molecular weight that is substantially the same of greater than at least one of the first ionic species' atomic weight and the first ionic species' molecular weight, and, annealing the semiconductor using a controlled diffusion annealing, where the abruptness of the profile is increased after annealing such that the junction dimensions of width and depth are minimized with respect to the junction dimensions of the as-implanted first ionic species profile. In such an embodiment, one or more of the at least one second ionic species can also be implanted before implanting the first ionic species. The post-implanting can include selecting the at least one second ionic species to form multi-charge carrier complexes with the first ionic species. The oxygen content can be controlled during annealing.

For the systems and methods, the implanting can be performed using at least one of beamline implantation, plasma doping, gas phase doping, epitaxial deposition doping, chemical vapor deposition. The first ionic species and the at least one second ionic species can include ions of at least one of Boron, Fluorine, Geranium, Silicon, Phosphorus, and Arsenic.

Other objects and advantages will become apparent hereinafter in view of the specification and drawings.

### BRIEF DESCRIPTION OF THE DRAWINGS

FIG. 1 is a plot comparing a Boron dopant ion as-implanted profile with simulated Boron recoils using various energy levels of Germanium as a post-implant;

FIG. 2 is a plot comparing a Boron dopant ion as-implanted profile with simulated Boron recoils using various concentrations of Germanium as a post-implant;

FIG. 3 is a plot comparing an as-implanted profile to profiles after annealing employing flash RTP;

FIG. 4 is a plot showing the effects of an oxygen-controlled environment on a profile distribution, when the oxygen control is employed during a controlled diffusion annealing;

FIGS. 5a, 5b and 5c illustrate flow charts for dopant diffusion and activation control according to embodiments of the present invention; and

FIG. 6 is a block diagram of an example of a thermal processing system according to an embodiment of the present invention.

### DESCRIPTION

To provide an overall understanding, certain illustrative embodiments will now be described; however, it will be understood by one of ordinary skill in the art that the systems and methods described herein can be adapted and modified to provide systems and methods for other suitable applications and that other additions and modifications can be made without departing from the scope of the systems and methods described herein.

Unless otherwise specified, the illustrated embodiments can be understood as providing exemplary features of varying detail of certain embodiments, and therefore features, components, modules, and/or aspects of the illustrations or processes can be otherwise combined, separated, interchanged, and/or rearranged without departing from the disclosed systems or methods.

Two factors can be considered when minimizing sheet resistance of a junction, including an ultra shallow junction. These factors include maximizing dopant activation, and maximizing an amount of dopant or species that produces charge carriers. This latter factor can be based on the uniformity of the activated dopant concentration throughout the junction. Unfortunately, the as-implanted profile can often be described as Gaussian, or more generally, non-uniform with a large concentration at the structure surface and a Gaussian-like decline in concentration as the junction depth increases. Accordingly, a desirable junction characteristic can include a uniform distribution of activated dopant that includes a “box-shaped” profile.

In one embodiment, the disclosed methods and systems include methods and systems for providing controlled redistribution of an as-implanted dopant profile rather than expansion of the as-implanted dopant profile. Accordingly, controlled redistribution can indicate that the abruptness of the profile is increased such that the width and depth of the as-implanted dopant profile is minimized with respect to the as-implanted dopant profile. Abruptness is defined as the rate of fall for the concentration per depth and is typically defined in units of nm/decade.

In one embodiment, the disclosed methods and systems include performing a controlled diffusion annealing technique in an oxygen-controlled environment. Some examples of oxygen control methods are described in U.S. Pat. No. 6,087,247 to Downey, the contents of which are herein incorporated by reference in their entirety. As provided in the aforementioned patent, during annealing, oxygen concentration can be controlled at or near a selected level in a range less than approximately 1000 parts per million (ppm) and preferably in a range of about 30-300 ppm. The oxygen concentration can be controlled by reducing the oxygen below a desired level by purging or vacuum pumping the chamber in which the athermal or Electromagnetic Induction Heating (EMIH) annealing is performed, and introducing a controlled amount of oxygen. In another embodiment, the chamber can be backfilled with a gas that includes oxygen at or near a selected oxygen concentration level. Other gas control techniques can also be used to create the desired oxygen concentration in the annealing chamber. Generally, the oxygen control technique includes providing an oxygen content greater than an ambient oxygen content.

The oxygen-controlled technique can be shown to affect certain aspects of the dopant profile during a controlled diffusion annealing. For example, the dopant profile regions at the surface of the junction that can be understood to include the peak region(s) of the Gaussian as-implanted profile, can be affected by (e.g., diffused for more even distribution, while maintaining the profile substantially the same) the oxygen-controlled conditions and/or environment during a controlled diffusion annealing technique, while the oxygen-controlled environment may not affect or otherwise diffuse the tail regions of the as-implanted dopant profile during a controlled diffusion annealing.

Although previously disclosed oxygen-controlled environments can include oxygen contents of less than approximately 1000 ppm, the oxygen content for the disclosed methods and systems can be based on factors including the type of controlled diffusion annealing, the temperature at which the controlled diffusion annealing is performed, the time for which the controlled diffusion annealing is performed, the dopant and/or “first ionic species” used, and as will be provided herein, in some embodiments, a second ionic species that can be used for profile redistribution.

As provided previously, the oxygen controlled environment can be provided during a controlled diffusion annealing. These controlled diffusion annealing techniques can provide dopant activation while providing a dopant profile (concentration versus junction depth) with dimensions (length, width, and depth) that are substantially the same as the as-implanted, non-uniform dopant profile. Controlled diffusion annealing techniques can include, for example, Solid Phase Epitaxy (SPE), Flash Rapid Thermal Annealing (RTP), Sub-melt laser annealing, microwave annealing, a RF annealing, and/or a low temperature rapid thermal annealing (LTRTA), although such examples are provided for illustration and not limitation, and those of ordinary skill in the art will understand that other non-diffusing annealing techniques that can be understood to occur in, for example, five seconds or less, can be employed by the disclosed methods and systems.

In some embodiments, the methods and systems can include implanting a second ionic species, where such implantation of a second ionic species can affect the profile of the as-implanted dopant (e.g., “first ionic species”) profile. The disclosed methods and systems can also refer to at least one second ionic species that can be different from the first ionic species. For example, a dopant for first ionic species can include ionic species of B, BF₂, As, P, etc., while the second ionic species can include ionic species of Ge, Si, F, etc., with such examples of first and second species being provided as an illustration and not for limitation. Generally, the second ionic species can have an atomic and/or molecular weight that is substantially the same or greater than the first ionic species. Accordingly, the second ionic species can be implanted after the first ionic species such that the atoms and/or molecules of the second ionic species can interact with (e.g., collide, “knock-on”) the atoms and/or molecules of the first ionic species to cause the atoms and/or molecules of the first ionic species (e.g., dopant) to diffuse from heavily concentrated regions (e.g., peak region(s) of the as-implanted Gaussian profile) to the less concentrated regions (e.g., tail regions of the as-implanted Gaussian profile). Once again, the overall dimensions of the as-implanted junction may not change substantially from the implantation of the second ionic species, but rather, the as-implanted distribution may be more even throughout the junction (e.g., “box-shaped” as compared to Gaussian).

Those with ordinary skill in the art will recognize that at least one of the second ionic species can additionally and optionally be implanted prior to implantation of the first ionic species, where such prior implantation can be used to prevent channeling of the first ionic species during implantation of the first ionic species. In an embodiment, the at least one second ionic species implanted before the first ionic species to prevent channeling, can be different from the at least one second ionic species implanted after the first ionic species, where the post-implant affects movement of the first ionic species within the as-implanted junction dimensions (e.g., within the profile of the as-implanted junction length, width, and depth).

The disclosed methods and systems can thus also include a controlled diffusion anneal process that can be performed after the implantation of the first and second ionic species. Accordingly, in an embodiment, the disclosed methods and systems can include implanting a first ionic species, implanting at least one second ionic species to redistribute the first ionic species' profile, and utilizing a controlled diffusion annealing technique as provided herein to activate the dopant. The disclosed methods and systems also include implanting an ionic species prior to the first ionic species, implanting the first ionic species, implanting a second ionic species to redistribute the first ionic species' profile (where the second ionic species may be the same as the ionic species implanted prior to the first ionic species), and performing a controlled diffusion annealing.

In some embodiments of the disclosed methods and systems, the aforementioned oxygen controlled (e.g., during annealing) methods and systems described herein can be combined with the “second ionic species” methods and systems. Accordingly, profile redistribution of the as-implanted profile can be performed by implanting at least a second ionic species at least after the first ionic species implantation, and annealing using a non-diffusing annealing technique while controlling the oxygen content of the ambient during annealing based on at least one of the annealing type, the temperature of annealing, the time of annealing, the first ionic species, and the second ionic species.

In some embodiments, the disclosed methods and systems can be applied in view of U.S. Ser. No. 09/835,653, entitled “Methods for Forming Ultrashallow Junctions with Low Sheet Resistance,” filed on Apr. 16, 2001, and naming Daniel F. Downey as inventor, the contents of which are herein incorporated by reference in their entirety, where U.S. Ser. No. 09/835,653 describes a method for forming a junction that includes introducing a dopant material into a surface layer of a semiconductor, where the dopant is selected to form charge carrier complexes that produce at least two charge carriers per complex upon activation. In such systems and methods, the dopant can include two ionic species selected to form the charge carrier complexes, a compound that includes two species to form the charge carrier complexes, and/or a dopant that can chemically bond with atoms of the semiconductor to form the charge carrier complexes. The dopant can thus be selected to form multi-charge or excitonic complexes. For example, the dopant can include BF, BGe, BSi, PF, PGe, PSi, AsF, AsGe, and AsSi, although such examples are provided for illustration and not limitation. In such systems, and with other disclosed embodiments, the implantation method or process can include beamline implantation, plasma doping, gas phase doping, epitaxial deposition doping, chemical vapor deposition, or another technique, where such techniques are also provided for illustration. Multiple doped layers can also be formed. Although activation processes for such excitonic methods can include thermal annealing, athermal annealing, laser annealing, rapid thermal processing (RTP/RTA), microwave annealing, radio frequency annealing, shock wave annealing, and furnace annealing, solid phase epitaxy (SPE) may also be considered. Accordingly, the previously disclosed methods and systems that include providing a first ionic species and a second ionic species where the second ionic species can assist in redistributing the first ionic species, can be combined with the methods and systems of U.S. Ser. No. 09/835,653, to provide a first ionic species redistribution where the first ionic species and the second ionic species are selected to form charge carrier complexes that produce at least two charge carriers per complex when activated. In such systems, SPE may be employed for activation and thus such annealing step can additionally and optionally be performed in an oxygen-controlled environment as provided previously herein.

In brief summary, this embodiment of the disclosed methods and systems can include selecting a first ionic species and at least one second ionic species, where such first ionic species and second ionic species are selected to form excitonic and/or multi-charge carrier complexes, and wherein the second ionic species can also be selected to cause redistribution of the first ionic species during implantation of the second ionic species. Additionally and optionally, a controlled diffusion annealing technique can be performed, such as SPE, where the annealing environment can include an oxygen-controlled environment.

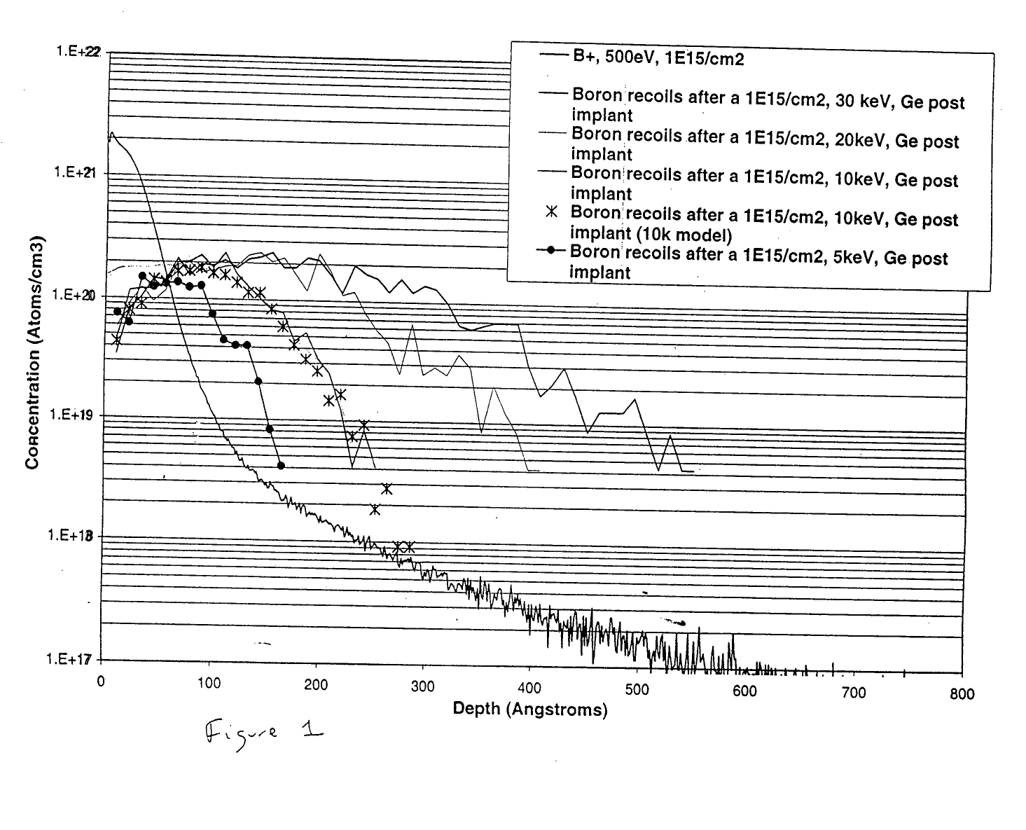

FIG. 1 provides a plot of dopant concentration (atoms/cm³) versus junction depth (angstroms) as provided by a Boron implant (e.g., “first ionic species”) and a Germanium post-implant (e.g., “second ionic species”) for various energy levels (e.g., junction depths). As FIG. 1 indicates, the Germanium post-implant can provide a redistribution of the Boron profile at the energy levels shown, with the redistribution providing a more box-shaped profile in all of the illustrated cases when compared to the Gaussian as-implanted profile. Furthermore, FIG. 1 indicates that dopant activation can be obtained deeper into the junction by utilizing different energy levels for the post-implant.

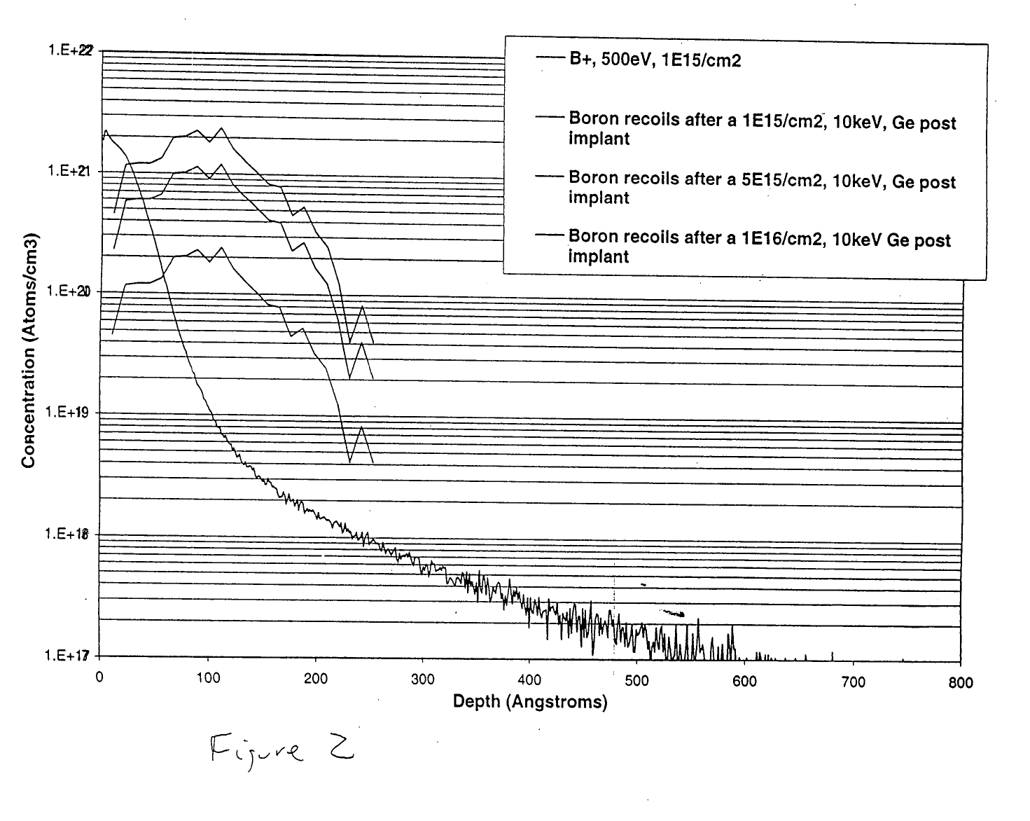

FIG. 2 provides a comparison of an as-implanted Boron implant at 500 eV and 1E15/cm² with Germanium post-implants of various concentrations including 1E15/cm², 5E15/cm², and 1E16/cm². For the various concentration levels of Germanium post-implant, the energy level remained at 10 keV. As FIG. 2 indicates, the Germanium post-implant profile shape can also alter or change the concentration to become more abrupt or a more box-shaped profile. Thereby, FIGS. 1 and 2 both illustrate the affects to the profile shape as to becoming more abrupt or box-shaped where FIG. 1 illustrates this affect as a result of a change in energy and FIG. 2 illustrates this affect as a result of a change in dose.

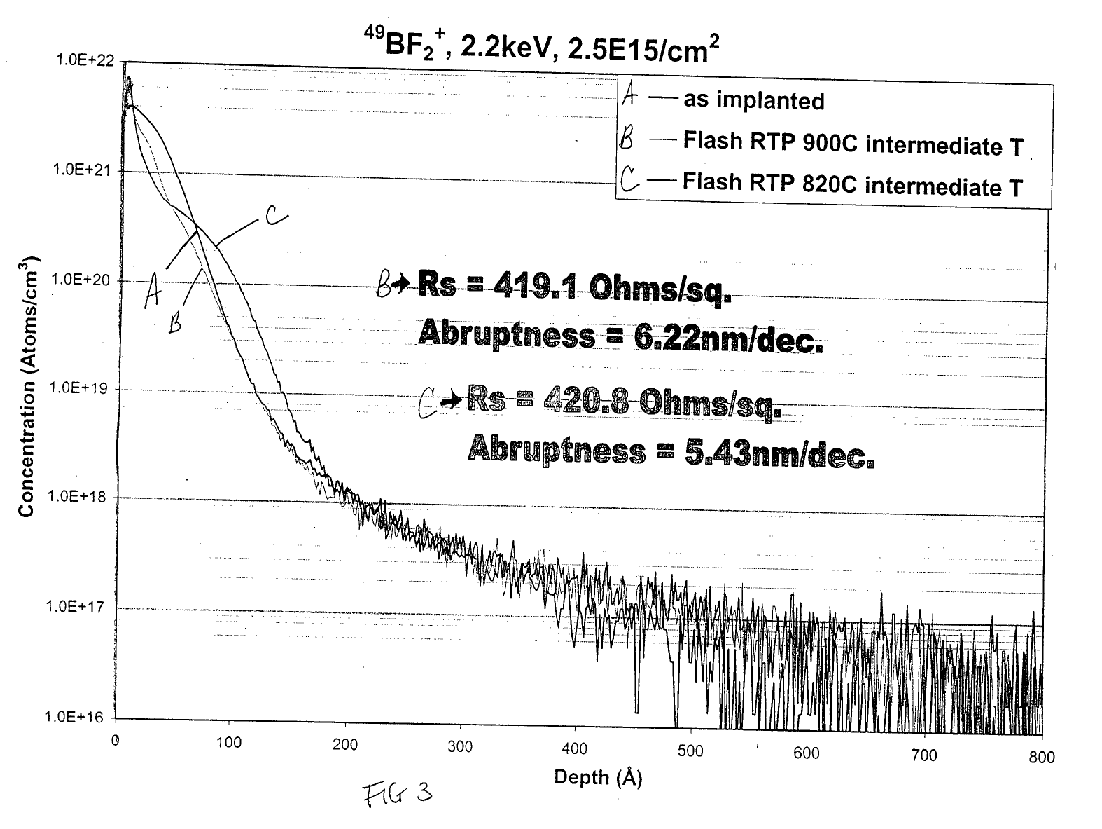

FIG. 3 provides comparisons of profiles for an as-implanted BF₂ implant, a flash RTP at 900 degrees Celsius, and a flash RTP at 820 degrees Celsius. FIG. 3 illustrates that annealing methods including RTP and other methods provided herein, can provide high activation (e.g., low sheet resistance) with minimal diffusion when compared to the as-implanted profile. Similarly, FIG. 4 illustrates the concepts provided previously herein with respect to oxygen-control. FIG. 4 compares an as-implanted BF₂ implant profile with oxygen-controlled environments of 100 ppm and twenty-one percent of the ambient, where such oxygen-control was provided during microwave anneal. As FIG. 4 indicates, the oxygen-controlled environments affect the peak region (e.g., surface) of the profile rather than the tail region (e.g., deeper region of junction).

What has thus been described are methods and systems for redistributing a dopant within a prescribed region, where the abruptness of the profile for such region is increased after the annealing. In one embodiment, the methods and systems include a controlled diffusion annealing process that can be performed in an oxygen-controlled environment. In an embodiment, the methods and systems can include selecting a first ionic species and at least one second ionic species, where the second ionic species can be implanted at least after the first ionic species, and where the second ionic species can be selected with an atomic and/or molecular weight that is substantially the same or greater than the first ionic species, such that the second ionic species can redistribute the first ionic species upon implantation of the at least one second ionic species. In some embodiments, the at least one second ionic species can be implanted prior to the first ionic species to prevent channeling of the first ionic species during implantation of the first ionic species. Furthermore, the first ionic species and the at least one second ionic species can be selected to form excitonic and/or multi-charge carrier complexes upon dopant activation. Some embodiments of the disclosed methods and systems can utilize one or all of the aforementioned options.

FIG. 6 is a block diagram of an example of a system for thermal processing of semiconductor wafers in accordance with an embodiment of the present invention. A thermal processor 50 includes a heater 52 mounted in a thermal processing chamber 54. A semiconductor wafer 60 is positioned in proximity to heater 52 for thermal processing at a selected temperature for a selected time. An example of suitable thermal processor 50 is a rapid thermal processor, such as Model SH 2800, manufactured by STEAG AST elektroniks. However, different rapid thermal processors and conventional thermal processing ovens may be utilized within the scope of the present invention.

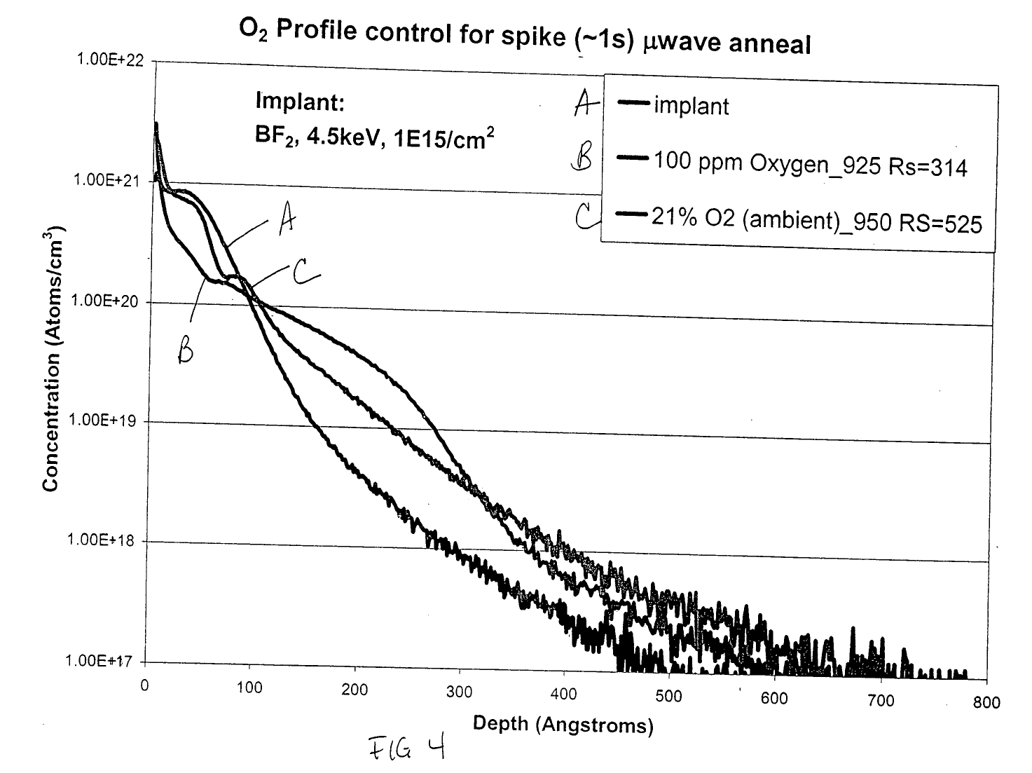

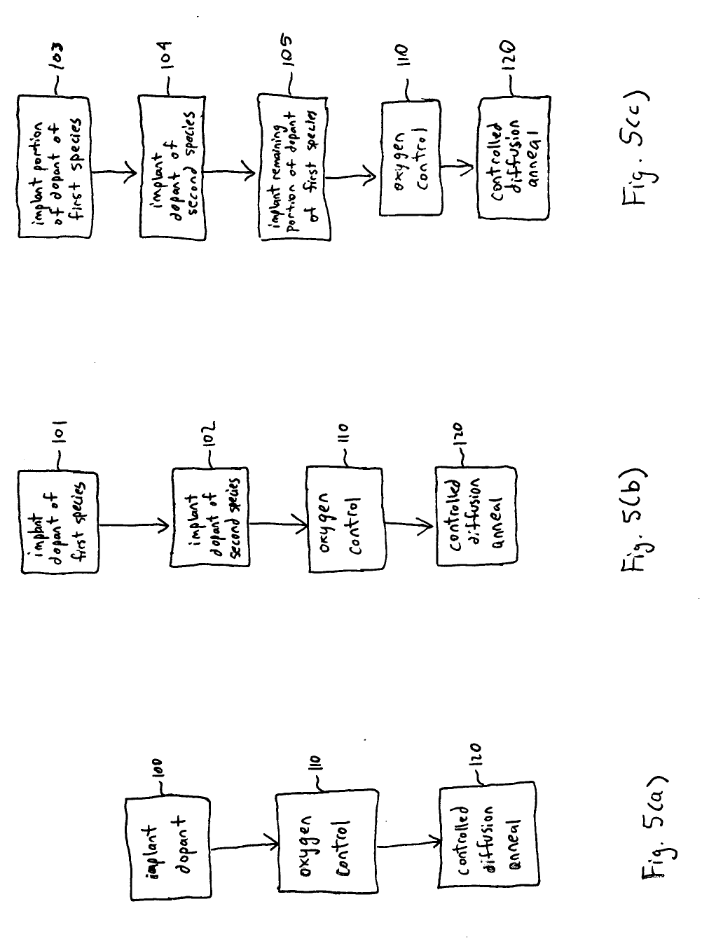

A flow diagram of the process steps associated with one embodiment of the present invention is illustrated in FIG. 5a. In step 100, a dopant material is implanted into a semiconductor wafer. The species, dose and energy of the dopant material are selected to produce an impurity region of a desired depth and conductivity in the semiconductor wafer. In step 110, the oxygen concentration is introduced and controlled. Then, a controlled diffusion anneal is performed at step 120. Process steps for another embodiment of the present invention are illustrated in FIG. 5b where a dopant material of a first ionic species is implanted into a semiconductor wafer at step 101. Next a dopant material of a second ionic species is implanted at step 102. Thereafter, the steps of oxygen control and controlled diffusion anneal are performed at steps 110 and 120 in a similar manner as in the first embodiment. In yet another embodiment of the present invention, a flow diagram of the process steps is illustrated in FIG. 5c. At step 103, a portion of a dopant material of a first ionic species is implanted into the semiconductor wafer. At step 104, a dopant material of a second ionic species is completely implanted. Then, the remaining portion of the dopant material of the first ionic species is implanted at step 105. Thereafter, the steps of oxygen control and controlled diffusion anneal are performed at steps 110 and 120 in a similar manner as in the first embodiment.

The thermal processing chamber 54 receives a process gas from a gas control system 62 through an inlet port 64. The process gas leaves thermal processing chamber 54 through an exhaust port 66. The gas control system 62 may include a process gas source 70 and an oxygen source 72. The process gas source 70 is typically a nitrogen source but may supply any other suitable process gas, including but not limited to argon and ammonia. The gas source 70 supplies gas through a mass flow controller 74 to the inlet port 64 of the thermal processor 50. Oxygen source 72 supplies oxygen through a mass flow controller 76 to the inlet port 64 of thermal processor 54. By appropriate adjustment of the mass flow controllers 74 and 76, the relative concentrations of oxygen and process gas supplied to the thermal processing chamber may be controlled. An oxygen monitor 80 is connected to output port 66 to measure the oxygen concentration in thermal processing chamber 54. In one example, the mass flow controllers 74 and 76 may each be a Bronkhorst Hi-Tec F2000 series.

The methods and systems described herein are not limited to a particular hardware or software configuration, and may find applicability in many computing or processing environments. The methods and systems can be implemented in hardware or software, or a combination of hardware and software. The methods and systems can be implemented in one or more computer programs, where a computer program can be understood to include one or more processor executable instructions. The computer program(s) can execute on one or more programmable processors, and can be stored on one or more storage medium readable by the processor (including volatile and non-volatile memory and/or storage elements), one or more input devices, and/or one or more output devices. The processor thus can access one or more input devices to obtain input data, and can access one or more output devices to communicate output data. The input and/or output devices can include one or more of the following: Random Access Memory (RAM), Redundant Array of Independent Disks (RAID), floppy drive, CD, DVD, magnetic disk, internal hard drive, external hard drive, memory stick, or other storage device capable of being accessed by a processor as provided herein, where such aforementioned examples are not exhaustive, and are for illustration and not limitation.

The computer program(s) is preferably implemented using one or more high level procedural or object-oriented programming languages to communicate with a computer system; however, the program(s) can be implemented in assembly or machine language, if desired. The language can be compiled or interpreted.

The processor(s) can thus be embedded in one or more devices that can be operated independently or together in a networked environment, where the network can include, for example, a Local Area Network (LAN), wide area network (WAN), and/or can include an intranet and/or the internet and/or another network. The network(s) can be wired or wireless or a combination thereof and can use one or more communications protocols to facilitate communications between the different processors. The processors can be configured for distributed processing and can utilize, in some embodiments, a client-server model as needed. Accordingly, the methods and systems can utilize multiple processors and/or processor devices, and the processor instructions can be divided amongst such single or multiple processor/devices.

The device(s) or computer systems that integrate with the processor(s) can include, for example, a personal computer(s), workstation (e.g., Sun, BP), personal digital assistant (PDA), handheld device such as cellular telephone, or another device capable of being integrated with a processor(s) that can operate as provided herein. Accordingly, the devices provided herein are not exhaustive and are provided for illustration and not limitation.

Although the methods and systems have been described relative to a specific embodiment thereof, they are not so limited. Obviously many modifications and variations may become apparent in light of the above teachings.

Many additional changes in the details, materials, and arrangement of parts, herein described and illustrated, can be made by those skilled in the art. Accordingly, it will be understood that the following claims are not to be limited to the embodiments disclosed herein, can include practices otherwise than specifically described, and are to be interpreted as broadly as allowed under the law.

1. A method for activating an ionic species implanted in a semiconductor, where an implanted profile includes a junction width and depth, the method comprising:
annealing the semiconductor using a controlled diffusion annealing, and, controlling an oxygen content during the annealing to redistribute an ionic species profile to increase the abruptness of the profile after the annealing.

2. A method according to claim 1, wherein a non-diffusing annealing includes at least one of: Solid Phase Epitaxy (SPE), Rapid Thermal Annealing (RTA), Flash RTP, sub-melt laser annealing, microwave annealing, and Radio Frequency (RF) annealing.

3. A method according to claim 1, wherein controlling the oxygen content includes determining an oxygen content based on at least one of the controlled diffusion annealing, a temperature at which the controlled diffusion annealing is performed, a time for which the controlled diffusion annealing is performed, a dopant, and a different ionic species from the first ionic species.

4. A method according to claim 3, wherein the dopant comprises Boron, Arsenic and Phosphorus.

5. A method for forming a junction in a semiconductor, the method comprising:
implanting a first ionic species in the semiconductor,
post-implanting at least one second ionic species where the at least one second ionic species includes at least one of an atomic weight and a molecular weight that is substantially the same or greater than at least one of the first ionic species' atomic weight and molecular weight, and,
annealing the semiconductor using a controlled diffusion annealing,
where the abruptness of a first ionic species profile after annealing is increased such that the junction dimensions are minimized with respect to an as-implanted profile of the first ionic species.

6. A method according to claim 5, further including implanting the at least one second ionic species before implanting the first ionic species.

7. A method according to claim 5, wherein post-implanting includes selecting the at least one second ionic species to form a multi-charge carrier complexes with the first ionic species.

8. A method according to claim 6, wherein implanting includes at least one of beamline implantation, plasma doping, gas phase doping, epitaxial deposition doping, chemical vapor deposition.

9. A method according to claim 5, wherein the first ionic species and the at least one second ionic species include ions of at least one of Boron, Fluorine, Geranium, Silicon, Phosphorus, and Arsenic.

10. A method according to claim 5, wherein annealing includes controlling oxygen content during annealing.

11. A method according to claim 5, wherein annealing includes controlling oxygen content based on at least one of the non-diffusing annealing, a temperature at which the non-diffusing annealing is performed, a time for which the non-diffusing annealing is performed, the first ionic species, and an ionic species other than the first ionic species.

12. A method for forming a junction in a semiconductor, the method comprising:
implanting a first ionic species in the semiconductor,
implanting at least one second ionic species, the at least one second ionic species based on at least one of:
forming a multi-charge carrier complexes with the first ionic species, and,
at least one of a molecular weight and an atomic weight of a second ionic species relative to the at least one of a molecular weight and an atomic weight of the first ionic species, and,
annealing the semiconductor using a controlled diffusion annealing, where the abruptness of a first ionic species profile is increased after annealing such that the junction dimensions are minimized with respect to an as-implanted profile of the first ionic species.

13. A method according to claim 12, further including implanting the at least one second ionic species before implanting the first ionic species.

14. A method according to claim 13, wherein the at least one second ionic species implanted before the first ionic species is the same as at least one of the at least one second ionic species implanted after the first ionic species.

15. A method according to claim 13, wherein the at least one second ionic species implanted before the first ionic species is different from the at least one second ionic species implanted after the first ionic species.

16. A method according to claim 12, wherein implanting the first ionic species includes at least one of beamline implantation, plasma doping, gas phase doping, epitaxial deposition doping, chemical vapor deposition.

17. A method according to claim 12, wherein implanting the at least one second ionic species includes at least one of beamline implantation, plasma doping, gas phase doping, epitaxial deposition doping, chemical vapor deposition.

18. A method according to claim 12, wherein the first ionic species and the at least one second ionic species include ions of at least one of Boron, Fluorine, Geranium, Silicon, Phosphorus, and Arsenic.

19. A method according to claim 12, wherein annealing includes controlling oxygen content during annealing.

20. A method according to claim 12, wherein annealing includes controlling oxygen content based on at least one of the controlled diffusion annealing, a temperature at which the controlled diffusion annealing is performed, a time for which the controlled diffusion annealing is performed, the first ionic species, and the at least one second ionic species.
